(19) United States
(12) Patent Application Publication
(10) Pub. No.: US 2025/0096746 A1
(43) Pub. Date: Mar. 20, 2025

(54) POWER MANAGEMENT CIRCUIT SUPPORTING FAST VOLTAGE SWITCHING WITH REDUCED RUSH CURRENT

(71) Applicant: Qorvo US, Inc., Greensboro, NC (US)

(72) Inventors: Nadim Khlat, Colomiers (FR); Jeffrey D. Potts, Mocksville, NC (US)

(21) Appl. No.: 18/293,523

(22) PCT Filed: Aug. 5, 2021
(86) PCT No.: PCT/US2021/044596

§ 371 Date: Jan. 30, 2024

(51) Int. Cl. H03F 3/189; H03F 1/02; H03F 3/24

(52) U.S. Cl. CPC H03F 3/189; H03F 1/0211; H03F 3/24

(57) ABSTRACT

A power management circuit supporting fast voltage switching with reduced rush current is provided. The power management circuit is configured to provide an average power tracking (APT) voltage to a power amplifier circuit for amplifying an analog signal. Moreover, the power management circuit must be able to adapt the APT voltage frequently and rapidly to enable such application as dynamic power control. In embodiments disclosed herein, the power management circuit can be configured to opportunistically activate a voltage amplifier, which is typically used to generate an envelope tracking (ET) voltage, at an appropriate time to help support fast switching of the APT voltage. As a result, the power management circuit is able to adapt the APT voltage frequently and rapidly. Furthermore, by utilizing the voltage amplifier to support fast switching of the APT voltage, it is also possible to reduce rush current in the power management circuit.

### FIELD OF THE DISCLOSURE

The technology of the disclosure relates generally to an envelope tracking (ET) and/or average power tracking (APT) power management circuit.

### BACKGROUND

Fifth-generation (5G) new radio (NR) (5G-NR) has been widely regarded as the next generation of wireless communication technology beyond the current third-generation (3G) and fourth-generation (4G) technologies. In this regard, a wireless communication device capable of supporting the 5G-NR wireless communication technology is expected to achieve higher data rates, improved coverage range, enhanced signaling efficiency, and reduced latency across a wide range of radio frequency (RF) bands, which include a low-band (below 1 GHz), a mid-band (1 GHz to 6 GHz), and a high-band (above 24 GHz).

Downlink and uplink transmissions in a 5G-NR system are widely based on orthogonal frequency division multiplexing (OFDM). In this regard, FIG. 1 is a schematic diagram of an exemplary OFDM time-frequency grid 10 illustrating at least one reserve block (RB 12) for physical resource allocation in the 5G-NR system. The OFDM time-frequency grid 10 includes a frequency axis 14 representing a frequency domain and a time axis 16 representing a time domain. Along the frequency axis 14, there are a number of subcarriers 18(1)-18(M). The subcarriers 18(1)-18(M) are orthogonally separated from each other by a subcarrier spacing (SCS) of 15 KHz, for example. Along the time axis 16, there are a number of OFDM symbols 20(1)-20(N). Each of the OFDM symbols 20(1)-20(N) is separated by a cyclic prefix (CP) (not shown) configured to act as a guard band to help overcome inter-symbol interference (ISI) between the OFDM symbols 20(1)-20(N). In the OFDM time-frequency grid 10, each intersection of the subcarriers 18(1)-18M) and the OFDM symbols 20(1)-20(N) defines a resource element (RE) 22.

In a 5G-NR communication system, an RF signal 24 can be modulated into multiple subcarriers among the subcarriers 18(1)-18(N) in the frequency domain (along the frequency axis 14) and multiple OFDM symbols among the OFDM symbols 20(1)-20(N) in the time domain (along the time axis 16). The table (Table 1) below summarizes OFDM configurations supported by the 5G-NR communication system.

TABLE 1

| | | | | OFDM | |
|---|---|---|---|---|---|
| | Slot | # of Slots | | Symbol | Modulation |
| SCS | Length | per | CP | Duration | Bandwidth |
| (KHz) | (μs) | Subframe | (μs) | (μs) | (MHz) |
| 15 | 1000 | 1 | 4.69 | 71.43 | 50 |
| 30 | 500 | 2 | 2.34 | 35.71 | 100 |
| 60 | 250 | 4 | 1.17 | 17.86 | 200 |
| 120 | 125 | 8 | 0.59 | 8.93 | 400 |

In the 5G-NR communication system, the RF signal 24 is typically modulated with a high modulation bandwidth in excess of 200 MHz. In this regard, according to Table 1, the SCS will be 120 KHz and a transition settling time between two consecutive OFDM symbols among the OFDM symbols 20(1)-20(N) (e.g., amplitude change of the RF signal) needs to be less than or equal to the CP duration of 0.59 μs.

In addition, the wireless communication device may also need to support such internet-of-things (IoT) applications as keyless car entry, remote garage door opening, contactless payment, mobile boarding pass, and so on.

Needless to say, the wireless communication device must also always make 911/E911 service accessible under emergency situations. As such, it is critical that the wireless communication device remains operable whenever needed.

Notably, the wireless communication device relies on a battery cell (e.g., Li-Ion battery) to power its operations and services. Despite recent advancement in battery technologies, the wireless communication device can run into a low battery situation from time to time. In this regard, it is desirable to prolong battery life concurrent to enabling fast voltage changes between the OFDM symbols 20(1)-20(N).

### SUMMARY

Embodiments of the disclosure relate to a power management circuit supporting fast voltage switching with reduced rush current. The power management circuit is configured to provide an average power tracking (APT) voltage to a power amplifier circuit for amplifying an analog signal. Moreover, the power management circuit must be able to adapt the APT voltage frequently and rapidly to enable such application as dynamic power control. In embodiments disclosed herein, the power management circuit can be configured to opportunistically activate a voltage amplifier, which is typically used to generate an envelope tracking (ET) voltage, at an appropriate time to help support fast switching of the APT voltage. As a result, the power management circuit is able to adapt the APT voltage frequently and rapidly. Furthermore, by utilizing the voltage amplifier to support fast switching of the APT voltage, it is also possible to reduce rush current in the power management circuit to help prolong battery life.

In one aspect, a power management circuit is provided. The power management circuit includes a voltage output that outputs an APT voltage to a power amplifier circuit for amplifying an analog signal. The power management circuit also includes a voltage amplifier coupled to the voltage output and configured to generate an ET voltage based on an ET target voltage and a supply voltage. The power management circuit also includes a control circuit. The control circuit is configured to receive a target voltage indicating that the APT voltage will change from a present voltage level in a present time interval to a future voltage level in an upcoming time interval. The control circuit is also configured to activate the voltage amplifier prior to a start of the upcoming time interval to thereby cause the APT voltage to change to the target voltage within a defined temporal limit from the start of the upcoming time interval.

In another aspect, a power management apparatus is provided. The power management apparatus includes a power amplifier circuit configured to amplify an analog signal based on an APT voltage. The power management apparatus also includes a power management circuit. The power management circuit includes a voltage output that outputs the APT voltage to the power amplifier circuit. The power management circuit also includes a voltage amplifier coupled to the voltage output and configured to generate an ET voltage based on an ET target voltage and a supply voltage. The power management circuit also includes a control circuit. The control circuit is configured to receive a target voltage indicating that the APT voltage will change from a present voltage level in a present time interval to a future voltage level in an upcoming time interval. The control circuit is also configured to activate the voltage amplifier prior to a start of the upcoming time interval to thereby cause the APT voltage to change to the target voltage within a defined temporal limit from the start of the upcoming time interval.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary orthogonal frequency division multiplexing (OFDM) time-frequency grid illustrating at least one reserve block (RB) for physical resource allocation;

FIG. 2 is a schematic diagram of an exemplary conventional power management circuit that can draw a large rush current during voltage switching;

FIG. 3 is a schematic diagram of an exemplary power management circuit configured according to an embodiment of the present disclosure to support fast voltage switching in a power management apparatus with reduced rush current;

FIG. 4 is a timing diagram providing an exemplary illustration of the power management circuit of FIG. 3 configured to increase an average power tracking (APT) voltage from a present voltage level in a present OFDM symbol to a future voltage level in an upcoming OFDM symbol; and

FIG. 5 is a timing diagram providing an exemplary illustration of the power management circuit of FIG. 3 configured to decrease an APT voltage from a present voltage level in a present OFDM symbol to a future voltage level in an upcoming OFDM symbol.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a power management circuit supporting fast voltage switching with reduced rush current. The power management circuit is configured to provide an average power tracking (APT) voltage to a power amplifier circuit for amplifying an analog signal. Moreover, the power management circuit must be able to adapt the APT voltage frequently and rapidly to enable such application as dynamic power control. In embodiments disclosed herein, the power management circuit can be configured to opportunistically activate a voltage amplifier, which is typically used to generate an envelope tracking (ET) voltage, at an appropriate time to help support fast switching of the APT voltage. As a result, the power management circuit is able to adapt the APT voltage frequently and rapidly. Furthermore, by utilizing the voltage amplifier to support fast switching of the APT voltage, it is also possible to reduce rush current in the power management circuit to help prolong battery life.

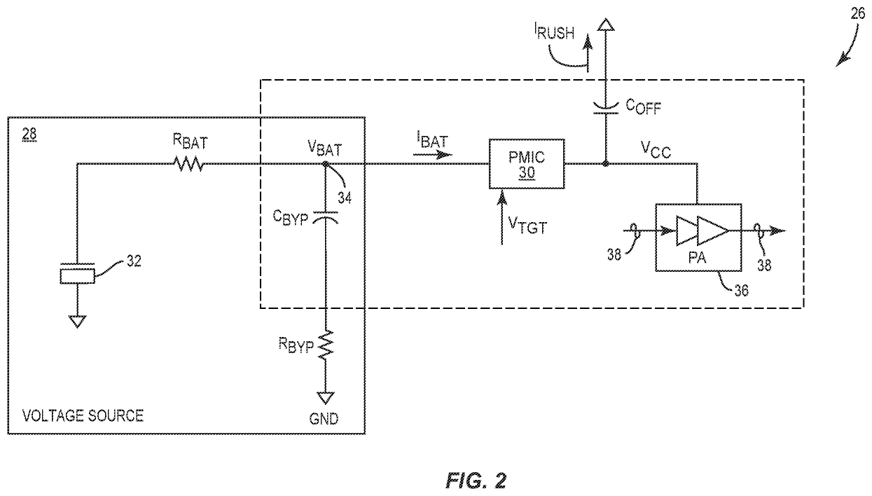

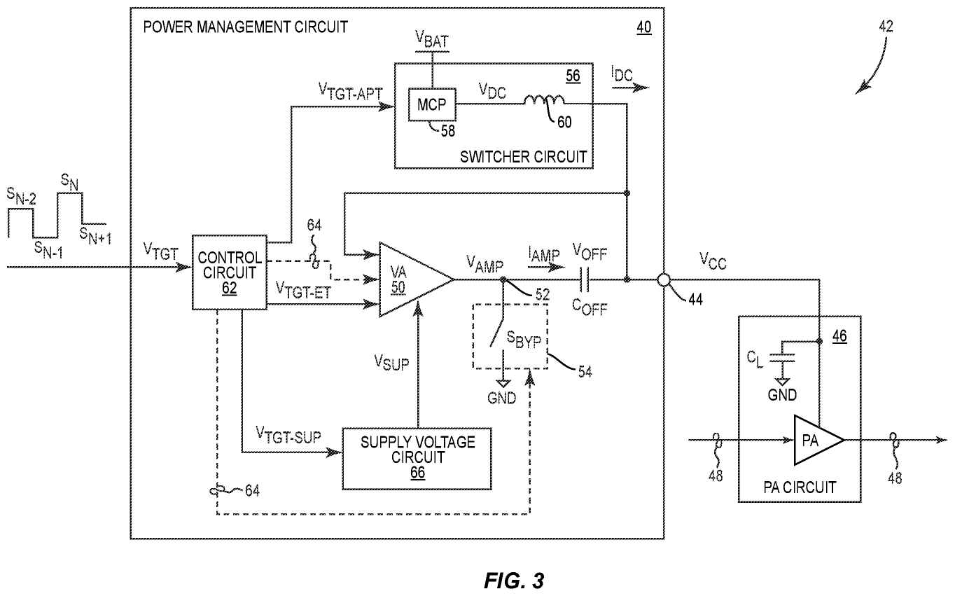

Before discussing the power management circuit according to the present disclosure, starting at FIG. 3, an overview of a conventional power management circuit that can draw a lager rush current during voltage switching is first provided with reference to FIG. 2.

FIG. 2 is a schematic diagram of an exemplary conventional power management circuit 26 that can draw a large rush current I_{RUSH} during voltage switching. The conventional power management circuit 26 includes a voltage source 28 and a power management integrated circuit (PMIC) 30. The voltage source 28 includes a battery 32 (e.g., a Li-Ion battery) that supplies a battery voltage V_{BAT} at a coupling node 34, which may be coupled to a ground (GND) via a capacitor C_{BYP} and a resistor R_{BYP}. The PMIC 30 is coupled to the coupling node 34 to receive the battery voltage V_{BAT} and draw a battery current I_{BAT}. Accordingly, the PMIC 30 is configured to generate an APT voltage V_{CC} based on the battery voltage V_{BAT} and provide the APT voltage V_{CC} to a power amplifier circuit 36 for amplifying an analog signal 38.

The analog signal 38 may be modulated across a wide modulation bandwidth, which can cause a large variation of RF current at the power amplifier circuit 36. As such, it is necessary to present a low impedance to the power amplifier circuit 36 to help reduce ripple in the APT voltage V_{CC} caused by the RF current. In this regard, the conventional power management circuit 26 typically includes an offset capacitor C_{OFF} to help reduce the impedance seen by the power amplifier circuit 36.

In addition to impedance matching, the offset capacitor C_{OFF} is also used to maintain the APT voltage V_{CC} at a desired voltage level. In this regard, the offset capacitor C_{OFF} needs to be charged whenever the APT voltage V_{CC} increases and discharged whenever the APT voltage V_{CC} decreases. As such, as shown in the equation (Eq. 1) below, a change rate (dV_{CC}/dt) of the APT voltage V_{CC} is dependent on how fast the offset capacitor C_{OFF} can be charged or discharged.

$${dV}_{CC} / dt = {I}_{RUSH} / {C}_{OFF} \qquad ( Eq . 1 )$$

In the equation (Eq. 1) above, I_{RUSH} represents a rush current associated with charging/discharging of the offset capacitor C_{OFF} and C_{OFF} represents a capacitance of the offset capacitor C_{OFF}. Particularly, when the offset capacitor C_{OFF} is charged in response to an increase of the APT voltage V_{CC}, the offset capacitor C_{OFF} draws the rush current I_{RUSH} from the battery 32. Given that the capacitance C_{OFF} is typically fixed and relatively large (e.g., 2.2 μF), the only way to reduce switching time of the APT voltage V_{CC} is to increase the rush current I_{RUSH}. For example, when the APT voltage V_{CC} changes from 1 V to 5.5 V within 0.59 μs, the rush current I_{RUSH} can be as high as 17 Amps (A), which can significantly reduce operating time of the battery 32.

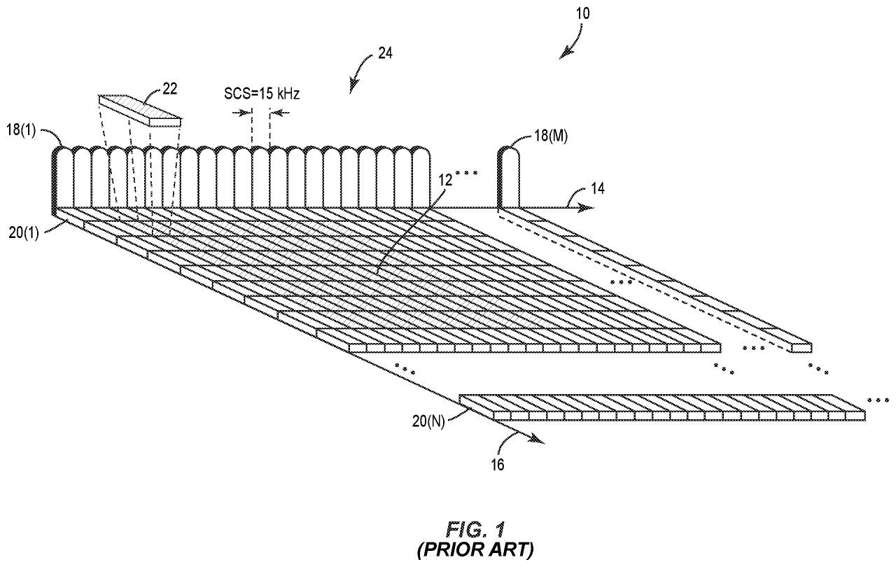

To avoid amplitude clipping to the analog signal 38 at the power amplifier circuit 36, the PMIC 30 is configured to generate the APT voltage V_{CC} in accordance with an APT target voltage V_{TGT} that corresponds to average power of the analog signal 38. As such, the APT voltage V_{CC} can swing from low to high, or vice versa, from time to time. When the conventional power management circuit 26 is provided in a legacy second generation (2G), third generation (3G), or even fourth generation (4G) wireless communication device, the APT voltage V_{CC} may change at a relatively slower rate. As such, the rush current I_{RUSH} may have a lesser impact on the battery 32. However, in a fifth generation (5G) new radio (5G-NR) wireless communication device, the APT voltage V_{CC} may need to change very frequently (e.g., between each of the OFDM symbols 20(1)-20(N) in FIG. 1) and rapidly (e.g., within the CP duration of 0.59 μs). As a result, the rush current I_{RUSH} can have a tremendous impact on battery life. As such, it is desirable to reduce the rush current I_{RUSH} concurrent to supporting fast and frequent switching of the APT voltage V_{CC}.

In this regard, FIG. 3 is a schematic diagram of an exemplary power management circuit 40 configured according to an embodiment of the present disclosure to support fast voltage switching in a power management apparatus 42 with reduced rush current. Herein, voltage switching refers to a voltage change (increase or decrease) from one voltage level to a different voltage level.

The power management circuit 40 includes a voltage output 44 that outputs an APT voltage V_{CC} to a power amplifier circuit 46 for amplifying an analog signal 48. The power management circuit 40 also includes a voltage amplifier 50 (denoted as “VA”). The voltage amplifier 50 is typically activated to generate an ET voltage V_{AMP} in accordance with an ET target voltage V_{TGT}-ET and based on a supply voltage V_{SUP}.

The power management circuit 40 also includes an offset capacitor C_{OFF} that is coupled between an output 52 of the voltage amplifier 50 and the voltage output 44. The power management circuit 40 also includes a switch circuit 54, which includes a bypass switch S_{BYP} coupled between the output 52 of the voltage amplifier 50 and the GND. When the bypass switch S_{BYP} is opened, the offset capacitor C_{OFF} will raise the ET voltage V_{AMP} by an offset voltage V_{OFF} to generate the APT voltage V_{CC} at the voltage output 44 (V_{CC}=V_{AMP}+V_{OFF}). In contrast, when the bypass switch S_{BYP} is closed, the offset capacitor C_{OFF} will be charged by a low-frequency current I_{DC} to thereby maintain the APT voltage V_{CC} at a desired voltage level. Further, when the bypass switch S_{BYP} is closed, the offset capacitor C_{OFF} also helps to reduce the impedance seen by the power amplifier circuit 46. In this regard, when the bypass switch S_{BYP} is closed, the offset capacitor C_{OFF} is functionally equivalent to the offset capacitor C_{OFF} in the conventional power management circuit 26 of FIG. 2. Accordingly, the low-frequency current I_{DC} drawn by the offset capacitor C_{OFF} can be equated with the rush current I_{RUSH} in FIG. 2.

As discussed in detail below, the power management circuit 40 can be configured to opportunistically activate and deactivate the voltage amplifier 50 at appropriate times to help enable fast switching of the APT voltage V_{CC} while concurrently reducing the rush current I_{DC} drawn by the offset capacitor C_{OFF}. As a result, the power management circuit 40 is able to adapt the APT voltage V_{CC} frequently and rapidly to support such applications as dynamic power control. Furthermore, by utilizing the voltage amplifier 50 to support fast switching of the APT voltage V_{CC}, it is also possible to reduce the rush current I_{DC} to help prolong battery life.

In embodiments disclosed herein, the power management circuit 40 is configured to adapt the APT voltage V_{CC} in between a pair of consecutive OFDM symbols S_{N-1} and S_{N}, which can be any pair of consecutive OFDM symbols among the OFDM symbols 20(1)-20(N) in FIG. 1. The OFDM symbol S_{N-1} is referred to as a preceding one of the pair of consecutive OFDM symbols S_{N-1} and S_{N}, and the OFDM symbol S_{N} is referred to as a succeeding one of the pair of consecutive OFDM symbols S_{N-1} and S_{N}. Understandably from FIG. 1, each of the OFDM symbols S_{N-1} and S_{N} includes a CP duration as configured according to Table 1.

In this regard, the power management circuit 40 is configured according to embodiments of the present disclosure to increase or decrease the APT voltage V_{CC} within the CP duration in each of the OFDM symbols S_{N-1} and S_{N}. However, it should be appreciated that the power management circuit 40 can also support fast switching of the APT voltage V_{CC} in other usage scenarios, such as adapting the APT voltage V_{CC} within an inter-frame spacing (IFS) in between two consecutive Wi-Fi frames.

The power management circuit 40 includes a switcher circuit 56. In a non-limiting example, the switcher circuit 56 includes a multi-level charge pump (MCP) 58 and a power inductor 60. The MCP 58 is configured to generate a low-frequency voltage V_{DC} based on a battery voltage V_{BAT} and in accordance with an APT target voltage V_{TGT-APT}. Depending on the APT target voltage V_{TGT-APT}, the MCP 58 may alternate the low-frequency voltage V_{DC} between different levels (e.g., 0V, V_{BAT}, or 2*V_{BAT}) based on an appropriate duty cycle. The power inductor 60, which is coupled between the MCP 58 and the voltage output 44, is configured to induce the low-frequency current I_{DC} for charging the offset capacitor C_{OFF}.

The power management circuit also includes a control circuit 62, which can be a field-programmable gate array (FPGA), as an example. The control circuit 62 is configured to receive a target voltage V_{TGT}, for example from a transceiver circuit (not shown). The target voltage V_{TGT} provides an early indication of the APT voltage V_{CC} in any of the OFDM symbols S_{N-1} and S_{N}. For example, the target voltage V_{TGT} received during OFDM symbol S_{N-1} may provide an indication of the APT voltage V_{CC} in the OFDM symbol S_{N}. As such, the control circuit 62 can determine, based on the target voltage V_{TGT}, that the APT voltage V_{CC} will change from one voltage level to another in the OFDM symbol S_{N} prior to a start of the OFDM symbol S_{N}. Accordingly, the control circuit 62 can generate the ET target voltage V_{TGT-ET} and the APT target voltage V_{TGT-APT} based on the target voltage V_{TGT} prior to the start of the OFDM symbol S_{N} to cause the power management circuit 40 to adapt the APT voltage V_{CC} within a defined temporal limit (e.g., the CP duration) from the start of the OFDM symbol S_{N}.

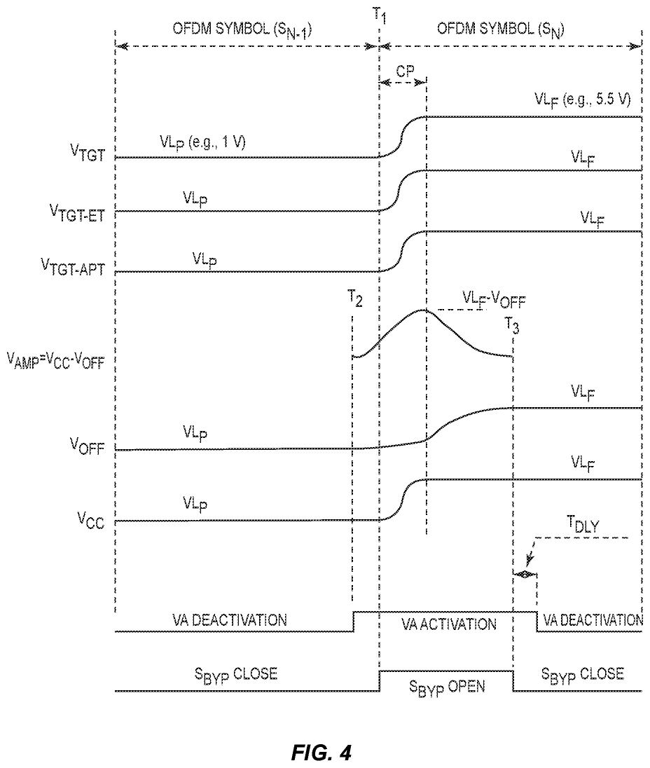

In one embodiment, the control circuit 62 determines (e.g., during OFDM symbol S_{N-1}) that the APT voltage V_{CC} is set to increase in the OFDM symbol S_{N}. In this regard, FIG. 4 is a timing diagram providing an exemplary illustration of the power management circuit 40 of FIG. 3 configured to increase the APT voltage V_{CC} from a present voltage level VL_{P} in OFDM symbol S_{N-1} (also referred to as “a present OFDM symbol” or “present time interval”) to a future voltage level VL_{F} in OFDM symbol S_{N} (also referred to as “an upcoming OFDM symbol” or “upcoming time interval”). Common elements between FIGS. 3 and 4 are shown therein with common element numbers and will not be re-described herein.

With reference to FIG. 4, the control circuit 62 receives the target voltage V_{TGT} during the OFDM symbol S_{N-1} and prior to a start time T₁ of the OFDM symbol S_{N}. The target voltage V_{TGT} indicates that the APT voltage V_{CC} is set to increase from the present voltage level VL_{P} (e.g., 1 V) in the OFDM symbol S_{N-1} to the future voltage level VL_{F} (e.g., 5.5 V) in the OFDM symbol S_{N}. Accordingly, the control circuit 62 generates the ET target voltage V_{TGT-ET} and the APT target voltage V_{TGT-APT} that are similar or identical to the target voltage V_{TGT}. Notably, during the OFDM symbol S_{N-1}, the bypass switch S_{BYP} is closed and the offset capacitor C_{OFF} is charged to maintain the APT voltage V_{CC} at the present voltage level VL_{P}.

Prior to the start time T₁ of the OFDM symbol S_{N} (e.g., at time T₂), the control circuit 62 activates the voltage amplifier 50 to generate the ET voltage V_{AMT} and source the high-frequency current I_{AMP} based on the ET target voltage V_{TGT-ET}. In a non-limiting example, the time T₂ can be so determined to account for ramping up and settling time of the voltage amplifier 50. In addition, the time T₂ can be further determined to ensure that the voltage amplifier 50 can ramp up the ET voltage V_{AMP} to a level substantially equal (VL_{F}−V_{OFF}) within the CP duration of the OFDM symbol S_{N}.

Concurrent to generating the ET voltage V_{AMP} to quickly raise the APT voltage V_{CC} to the level of (VL_{F}−V_{OFF}), the high-frequency current I_{AMP} will charge up a load capacitor C_{L} to help maintain the APT voltage V_{CC} at the level of (VL_{F}−V_{OFF}). The load capacitor C_{L}, which may be provided inside or outside the power amplifier circuit 46, has a smaller capacitance (e.g., 500 pF) compared to the offset capacitor C_{OFF}. As a result, according to equation (Eq. 1), it is possible to charge up the load capacitor C_{L} quickly with a reduced amount of rush current.

At the start time T₁ of the OFDM symbol S_{N}, the control circuit 62 opens the bypass switch S_{BYP} such that the offset capacitor C_{OFF} can be charged by the low-frequency current I_{DC} to raise the offset voltage V_{OFF} from the present voltage level VL_{P} to the future voltage level VL_{F}. Given that the APT voltage V_{CC} has already been raised by the voltage amplifier 50 and maintained by the load capacitor C_{L}, it is thus possible to charge the offset capacitor C_{OFF} at a slower rate to help further reduce demand for the low-frequency current I_{DC} (a.k.a., rush current). As the offset voltage V_{OFF} gradually increases, the voltage amplifier 50 can gradually reduce the ET voltage V_{AMP} such that a sum of the ET voltage V_{AMP} and the offset voltage V_{OFF} would equal the future voltage level VL_{F}.

At time T₃, the offset voltage V_{OFF} is raised to the future voltage value VL_{F}. In this regard, the ET voltage V_{AMP} is no longer needed. Accordingly, the control circuit 62 can close the bypass switch S_{BYP} and deactivate the voltage amplifier 50. In one embodiment, the control circuit 62 may close the bypass switch S_{BYP} and deactivate the voltage amplifier 50 concurrently at time T₃. Alternatively, the control circuit 62 may deactivate the voltage amplifier 50 with a timing delay T_{DLY} from closing the bypass switch S_{BYP}.

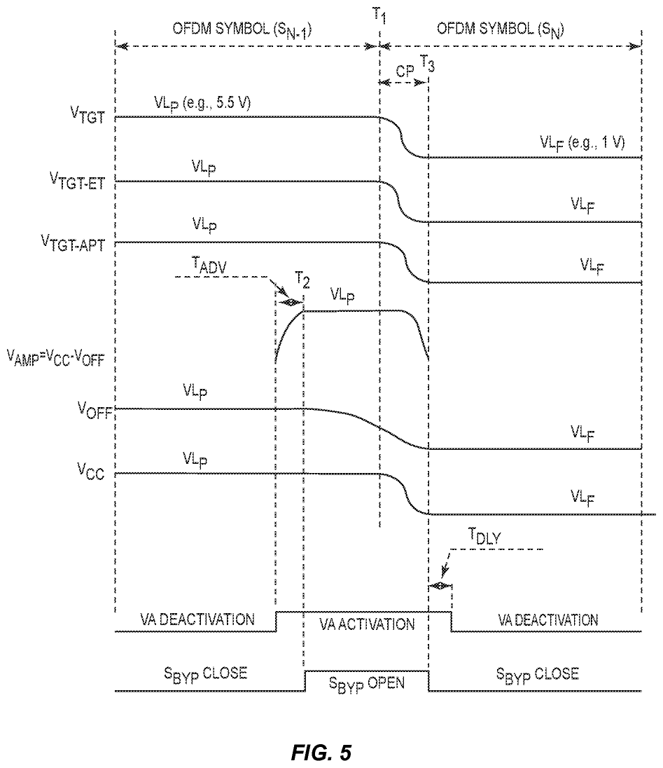

FIG. 5 is a timing diagram providing an exemplary illustration of the power management circuit 40 of FIG. 3 configured to decrease the APT voltage V_{CC} from a present voltage level VL_{P} in OFDM symbol S_{N-1} (also referred to as “a present OFDM symbol”) to a future voltage level VL_{F} in OFDM symbol S_{N} (also referred to as “an upcoming OFDM symbol”). Common elements between FIGS. 3 and 5 are shown therein with common element numbers and will not be re-described herein.

With reference to FIG. 5, the control circuit 62 receives the target voltage V_{TGT} during the OFDM symbol S_{N-1} and prior to a start time T₁ of the OFDM symbol S_{N}. The target voltage V_{TGT} indicates that the APT voltage V_{CC} is set to decrease from the present voltage level VL_{P} (e.g., 5.5 V) in the OFDM symbol S_{N-1} to the future voltage level VL_{F} (e.g., 1 V) in the OFDM symbol S_{N}. Accordingly, the control circuit 62 generates the ET target voltage V_{TGT-ET} and the APT target voltage V_{TGT-APT} that are similar or identical to the target voltage V_{TGT}. Notably, during the OFDM symbol S_{N-1}, the bypass switch S_{BYP} is closed and the offset capacitor C_{OFF} is charged to maintain the APT voltage V_{CC} at the present voltage level VL_{P}.

Prior to the start time T₁ of the OFDM symbol S_{N} (e.g., at time T₂), the control circuit 62 opens the bypass switch S_{BYP} to discharge the offset capacitor C_{OFF} to reduce the offset voltage V_{OFF} from the present voltage level VL_{P} to the future voltage level VL_{F}. The time T₂ may be so determined to ensure that the offset voltage V_{OFF} can be reduced to the future voltage level VL_{F} within the CP duration of the OFDM symbol S_{N}.

Notably, the power management circuit 40 still needs to maintain the APT voltage V_{CC} at the present voltage level VL_{P} during the OFDM symbol S_{N-1} while the offset capacitor C_{OFF} is discharged to reduce the offset voltage V_{OFF}. In this regard, the control circuit 62 is further configured to activate the voltage amplifier 50 to help maintain the APT voltage V_{CC} at the present voltage level VL_{P} before discharging the offset capacitor C_{OFF}. In addition, the voltage amplifier 50 also serves as a current sink to absorb discharge current associated with discharging the offset capacitor C_{OFF}. The control circuit 62 may activate the voltage amplifier 50 with a timing advance T_{ADV} before opening the bypass switch S_{BYP} to start discharging the offset capacitor C_{OFF}. The timing advance T_{ADV} may be so determined to ensure that the voltage amplifier 50 can be ramped up and settled to maintain the APT voltage V_{CC} at the present voltage level VL_{P} by the time T₂.

At time T₃, the offset voltage V_{OFF} is reduced to the future voltage value VL_{F}. In this regard, the ET voltage V_{AMP} is no longer needed. Accordingly, the control circuit 62 can close the bypass switch S_{BYP} and deactivate the voltage amplifier 50. In one embodiment, the control circuit 62 may close the bypass switch S_{BYP} and deactivate the voltage amplifier 50 concurrently at time T₃. Alternatively, the control circuit 62 may deactivate the voltage amplifier 50 with a timing delay T_{DLY} from closing the bypass switch S_{BYP}.

With reference back to FIG. 3, the control circuit 62 may activate/deactivate the voltage amplifier 50 and open/close the bypass switch S_{BYP} based on a control signal 64. The power management circuit 40 also includes a supply voltage circuit 66 configured to generate the supply voltage V_{SUP} for the voltage amplifier 50 based on a supply target voltage V_{TGT-SUP}. The control circuit 62 may further generate the supply target voltage V_{TGT-SUP} based on the target voltage V_{TGT}.

Those skilled in the art will recognize improvements and modifications to the preferred embodiments of the present disclosure. All such improvements and modifications are considered within the scope of the concepts disclosed herein and the claims that follow.

1. A power management circuit comprising:
a voltage output that outputs an average power tracking (APT) voltage to a power amplifier circuit for amplifying an analog signal;
a voltage amplifier coupled to the voltage output and configured to generate an envelope tracking (ET) voltage based on an ET target voltage and a supply voltage; and
a control circuit configured to:
receive a target voltage indicating that the APT voltage will change from a present voltage level in a present time interval to a future voltage level in an upcoming time interval; and
activate the voltage amplifier prior to a start of the upcoming time interval to thereby cause the APT voltage to change to the target voltage within a defined temporal limit from the start of the upcoming time interval.

2. The power management circuit of claim 1, wherein:
the present time interval corresponds to a preceding one of a pair of consecutive orthogonal frequency division multiplexing (OFDM) symbols;
the upcoming time interval corresponds to a succeeding one of the pair of consecutive OFDM symbols; and
the defined temporal limit corresponds to a cyclic prefix (CP) in each of the pair of consecutive OFDM symbols.

3. The power management circuit of claim 1, wherein the control circuit is further configured to generate the ET target voltage based on the target voltage.

4. The power management circuit of claim 1, further comprising:
a switcher circuit coupled to the voltage output and configured to generate a low-frequency current based on an APT target voltage;
an offset capacitor coupled between an output of the voltage amplifier and the voltage output and configured to raise the ET voltage by an offset voltage to generate the APT voltage at the voltage output; and
a bypass switch coupled between the output of the voltage amplifier and a ground.

5. The power management circuit of claim 4, wherein the control circuit is further configured to:
receive the target voltage indicating that the APT voltage will increase from the present voltage level to the future voltage level; and
activate the voltage amplifier prior to the start of the upcoming time interval to thereby raise the APT voltage from the present voltage level to the future voltage level within the defined temporal limit.

6. The power management circuit of claim 5, wherein the control circuit is further configured to:
generate the APT target voltage based on the target voltage; and
control the switcher circuit to generate the low-frequency current based on the APT target voltage.

7. The power management circuit of claim 6, wherein the control circuit is further configured to open the bypass switch after activating the voltage amplifier to thereby charge the offset capacitor from the present voltage level to the future voltage level based on the low-frequency current.

8. The power management circuit of claim 7, wherein the control circuit is further configured to close the bypass switch in response to the offset voltage being charged up to the future voltage level.

9. The power management circuit of claim 8, wherein the control circuit is further configured to deactivate the voltage amplifier after closing the bypass switch.

10. The power management circuit of claim 8, wherein the control circuit is further configured to deactivate the voltage amplifier and close the bypass switch concurrently.

11. The power management circuit of claim 4, wherein the control circuit is further configured to:
receive the target voltage indicating that the APT voltage will decrease from the present voltage level to the future voltage level; and
activate the voltage amplifier prior to the start of the upcoming time interval to thereby maintain the APT voltage at the present voltage level.

12. The power management circuit of claim 11, wherein the control is further configured to open the bypass switch after activating the voltage amplifier and prior to the start of the upcoming time interval to thereby discharge the offset capacitor from the present voltage level to the future voltage level within the defined temporal limit.

13. The power management circuit of claim 12, wherein the control circuit is further configured to close the bypass switch in response to the offset capacitor being discharged to the future voltage level.

14. The power management circuit of claim 13, wherein the control circuit is further configured to deactivate the voltage amplifier after closing the bypass switch.

15. The power management circuit of claim 13, wherein the control circuit is further configured to deactivate the voltage amplifier and close the bypass switch concurrently.

16. The power management circuit of claim 1, further comprising a supply voltage circuit configured to generate the supply voltage based on a supply target voltage.

17. The power management circuit of claim 16, wherein the control circuit is further configured to generate the supply target voltage based on the target voltage.

18. A power management apparatus comprising:
a power amplifier circuit configured to amplify an analog signal based on an average power tracking (APT) voltage; and
a power management circuit comprising:
a voltage output that outputs the APT voltage to the power amplifier circuit;
a voltage amplifier coupled to the voltage output and configured to generate an envelope tracking (ET) voltage based on an ET target voltage and a supply voltage; and
a control circuit configured to:
receive a target voltage indicating that the APT voltage will change from a present voltage level in a present time interval to a future voltage level in an upcoming time interval; and
activate the voltage amplifier prior to a start of the upcoming time interval to thereby cause the APT voltage to change to the target voltage within a defined temporal limit from the start of the upcoming time interval.

19. The power management apparatus of claim 18, wherein the power management circuit further comprises:
a switcher circuit coupled to the voltage output and configured to generate a low-frequency current based on an APT target voltage;
an offset capacitor coupled between an output of the voltage amplifier and the voltage output and configured to raise the ET voltage by an offset voltage to generate the APT voltage at the voltage output; and
a bypass switch coupled between the output of the voltage amplifier and a ground.

20. The power management apparatus of claim 19, wherein the power amplifier circuit comprises a load capacitor having a smaller capacitance than the offset capacitor.
